(19) United States
(12) Patent Application Publication
(10) Pub. No.: US 2023/0009003 A1
(43) Pub. Date: Jan. 12, 2023

(54) COLLATING DEVICE, LEARNING DEVICE, AND PROGRAM

(71) Applicant: KONICA MINOLTA, INC., Tokyo (JP)

(72) Inventors: Takumi ISHIWATA, Mitaka-shi, Tokyo (JP); Ippei ENOKIDA, Toyohashi-shi, Aichi (JP); Takeshi HAKII, Midori-ku, Sagamihara-shi, Kanagawa (JP)

(21) Appl. No.: 17/783,411

(22) PCT Filed: Aug. 26, 2020
(86) PCT No.: PCT/JP2020/032253

§ 371 Date: Jun. 8, 2022

(30) Foreign Application Priority Data
Dec. 12, 2019 (JP) 2019-224160

(51) Int. Cl. G01R 23/02; G06K 17/00

(52) U.S. Cl. CPC G01R 23/02; G06K 17/0029

(57) ABSTRACT

A chipless RFID tag can be scanned with high accuracy and robustness. A tag reader includes: a processing part configured to output information calculated from an emergent wave having an incident wave, as a radio wave irradiated to a tag (an object to be identified) emerged by way of the tag; and a determining part configured to identify attributes of the tag, using the information.

### TECHNICAL FIELD

The present invention relates to a collating device, a learning device, and a program for scanning a chipless RFID (Radio Frequency IDentification).

### BACKGROUND

RFID tags have become widespread in a variety of areas, including product management at retail stores, management of lending goods, inspection of goods entering and dispatching from a warehouse, and batch inspection of multiple goods. While RFID tags cost less than 10 yen, the cost has not yet been reduced to a level at which RFID tags can be attached to products priced at several tens of yen, for example, for use in commodity management and checkout. This is because a conventional RFID tag is composed of a memory and a control circuit in addition to an antenna, and thus there is a limit to lower the cost.

One RFID technology for lowering the cost is chipless RFID approach to have no memory or no control circuit (chip) and to be configured with only an antenna for scanning identification information. A chipless RFID tag can be fabricated by printing with metal ink or transferring metal foil. A chipless RFID tag can be formed by printing or transferring foil onto boxes or wrapping paper (product packages) for containing products, for example, and are therefore very inexpensive. Note that the chipless RFID tag printed on the product package does not have a shape of a conventional RFID tag, but it is still called a chipless RFID tag or simply an RFID tag, or just a tag in short, inclusive of the product package or the printed part of the product package.

In order to scan the identification information of a chipless RFID tag, it is necessary to identify a resonance frequency according to the shape of the RFID tag serving as an antenna. Non-Patent Document 1 describes a technique for scanning an RFID tag with a “U” shaped slot. In particular, the identification information determines the presence or absence and length of the slot, and the resonance frequency varies according to the presence or absence and length of this slot. The tag reader measures intensity of a signal (a ratio of intensity of an emergent wave to that of an incident wave) depending on the frequency, to detect the resonance frequency and scan the identification information.

### PRIOR ART DOCUMENTS

### Non-Patent Documents

Non-Patent Document 1: Md Aminul Islam and Nemai Chandra Karmakar, “Real-World Implementation Challenges of a Novel Dual-Polarized Compact Printable Chipless RFID Tag,” IEEE TRANSACTIONS ON MICROWAVE THEORY AND TECHNIQUES, VOL. 63, NO. 12, pp. 4581-4591, DECEMBER 2015.

### SUMMARY

Unlike in an experimental environment, the position and orientation of an RFID tag with respect to the tag reader may be different every time it is scanned and/or things other than the RFID tag may exist in vicinity to the RFID tag, in real-life situations where an RFID tag is used. As a result, the tag reader is often unable to identify the resonance frequency and fails to scan the identification information. The present invention has been devised in view of such a background, and is intended to provide a collating device, a learning device, and a program for scanning a chipless RFID tag with high accuracy and robustness.

### <First Aspect>

A collating device includes: a processing part configured to output information calculated from an emergent wave having an incident wave, as a radio wave irradiated to an object to be identified, emerged by way of the object; and a determining part configured to identify one or more attributes of the object, using the information.

### <Second Aspect>

In the collating device as described in First Aspect, the information includes at least intensity of the emergent wave.

### <Third Aspect>

In the collating device as described in Second Aspect, the information includes the at least intensity of the emergent wave at every frequency analysis point.

### <Fourth Aspect>

In the collating device as described in First Aspect, the information is a ratio of intensity of the emergent wave to that of the incident wave and/or a phase difference between the incident wave and the emergent wave, at every frequency analysis point.

### <Fifth Aspect>

In the collating device as described in First Aspect, the processing part collects waves having a bandwidth of 300 MHz or more and uses two or more frequency analysis points within the bandwidth to calculate the information.

### <Sixth Aspect>

In the collating device as described in First Aspect, the information is at least one of intensity of the emergent wave, a ratio of the intensity of the emergent wave to that of the incident wave, and a phase difference between the incident wave and the emergent wave, at every frequency analysis point in time domain.

### <Seventh Aspect>

In the collating device as described in First Aspect, the one or more attributes are given by one or more antenna elements of the object.

### <Eighth Aspect>

In the collating device as described in Seventh Aspect, the determining part uses, as the information, at least one of intensity of the emergent wave, a ratio of the intensity of the emergent wave to that of the incident wave, and a phase difference between the incident wave and the emergent wave, at every frequency analysis point other than resonance frequencies of the one or more antenna elements.

### <Ninth Aspect>

In the collating device as described in Seventh Aspect, the attributes of the object are identified by the determining part, even in a case where there are no peaks in at least one of intensity of the emergent wave, a ratio of the intensity of the emergent wave to that of the incident wave, and a phase difference between the incident wave and the emergent wave, at resonance frequencies of the one or more antenna elements of the object.

### <Tenth Aspect>

In the collating device as described in Seventh Aspect, the determining part uses, as the information, at least one of intensity of the emergent wave, a ratio of the intensity of the emergent wave to that of the incident wave, and a phase difference between the incident wave and the emergent wave, at each of frequency analysis points the number of which is greater than that of the identified one or more attributes of the object.

### <Eleventh Aspect>

In the collating device as described in First Aspect, the one or more attributes include an orientation of the object.

### <Twelfth Aspect>

In the collating device as described in First Aspect, the determining part identifies the one or more attributes of the object, based on a degree of similarity of the information to registered information on the one or more attributes of the object.

### <Thirteenth Aspect>

In the collating device as described in First Aspect, the determining part identifies the one or more attributes of the object, using a machine learning model.

### <Fourteenth Aspect>

In the collating device as described in Thirteenth Aspect, the machine learning model results from learning teaching data having pieces of information on the one or more attributes obtained from the object associated with labels of the one or more attributes.

### <Fifteenth Aspect>

In the collating device as described in Fourteenth Aspect, the teaching data includes data in a case where there are no peaks in at least one of intensity of the emergent wave, a ratio of the intensity of the emergent wave to that of the incident wave, and a phase difference between the incident wave and the emergent wave, at resonance frequencies of the one or more antenna elements of the object.

### <Sixteenth Aspect>

In the collating device as described in Thirteenth Aspect, the machine learning model uses one of the SVM (Support Vector Machine), k-nearest neighbor algorithm, and random forests.

### <Seventeenth Aspect>

In the collating device as described in Thirteenth Aspect, the machine learning model uses ensemble leaning including at least one of the SVM, k-nearest neighbor algorithm, and random forests.

### <Eighteenth Aspect>

In the collating device as described in Thirteenth Aspect, hyperparameters of the machine learning model are optimized with a grid search.

### <Nineteenth Aspect>

A learning device includes: a processing part configured to output information calculated from an emergent wave having an incident wave, as a radio wave irradiated to an object to be identified, emerged by way of the object; and a leaning part configured to create a machine learning model by learning teaching data having the information associated with labels of one or more attributes of the object.

### <Twentieth Aspect>

In the leaning device as claimed in Nineteenth Aspect, the teaching data includes pieces of information calculated from emergent waves measured with positions or orientations of the object being respectively different from one another with respect to an antenna radiating the incident wave and an antenna receiving the emergent wave.

### <Twenty-first Aspect>

In the leaning device as claimed in Nineteenth Aspect, each of the teaching data is information calculated from the emergent wave measured with a conducting or dielectric substance arranged within a predetermined distance from the object.

### <Twenty-second Aspect>

A program causes a computer, having an antenna, to execute: a step of outputting information calculated from an emergent wave having an incident wave, as a radio wave irradiated to an object to be identified, emerged by way of the object; and a step of identifying one or more attributes of the object, using the information.

### <Twenty-third Aspect>

A program causes a computer, having an antenna, to execute: a step of outputting information calculated from an emergent wave having an incident wave, as a radio wave irradiated to an object to be identified, emerged by way of the object; and a step of creating a machine learning model by learning teaching data having the information associated with labels of one or more attributes of the object.

The present invention provides a collating device, a learning device, and a program for scanning a chipless RFID tag with high accuracy and robustness.

### BRIEF DESCRIPTION OF DRAWINGS

FIG. 1 is a functional block diagram of a tag reader according to an embodiment of the present invention.

FIG. 2 shows a tag with identification information different from that of a tag of the embodiment.

FIG. 3 shows a tag in a shape different from that of the tag of the embodiment.

FIG. 4 shows a tag of a transmissive type different from a type of the tag of the embodiment.

FIG. 5 is a first chart to show a frequency spectrum of an emergent wave by way of the tag of the embodiment.

FIG. 6 is a second chart to show a frequency spectrum of an emergent wave by way of the tag of the embodiment.

FIG. 7 is a third chart to show a frequency spectrum of an emergent wave by way of the tag of the embodiment.

FIG. 8 is a flowchart of a procedure of the embodiment, to collect teaching data and execute a learning process.

FIG. 9 is a flowchart of an obtaining process of the embodiment.

FIG. 10 is a chart to show an intensity ratio in the time domain, according to a modification of the embodiment.

FIG. 11 is a chart to show a phase difference in the frequency domain, according to a modification of the embodiment.

### DETAILED DESCRIPTION OF EMBODIMENTS

Hereinbelow, a description is given of a tag reader according to an embodiment of the present invention. The tag reader irradiates a chipless RFID tag (RFID tag, or simply tag) with an incident radio wave and obtains tag information (identification information) from a frequency spectrum of an emergent wave by way of the tag. A conventional method obtains identification information by identifying a resonance frequency. However, it is often difficult to identify the resonance frequency because the frequency spectrum varies depending on a position and orientation of the tag, as well as objects in vicinity to the tag.

This tag reader of the embodiment uses a machine learning technique to determine identification information from the frequency spectrum. In particular, the tag reader uses a learning model (machine learning model), which has learned frequency spectrum information labeled with identification information, to scan (obtain, determine, or collate) identification information. Using the machine learning technique allows for obtaining identification information, even if the position and/or orientation of the tag is shifted or there is/are (an) object(s) in vicinity to the tag. Note that phase characteristics may be used instead of the frequency spectrum.

### <<Configuration of Tag Reader>>

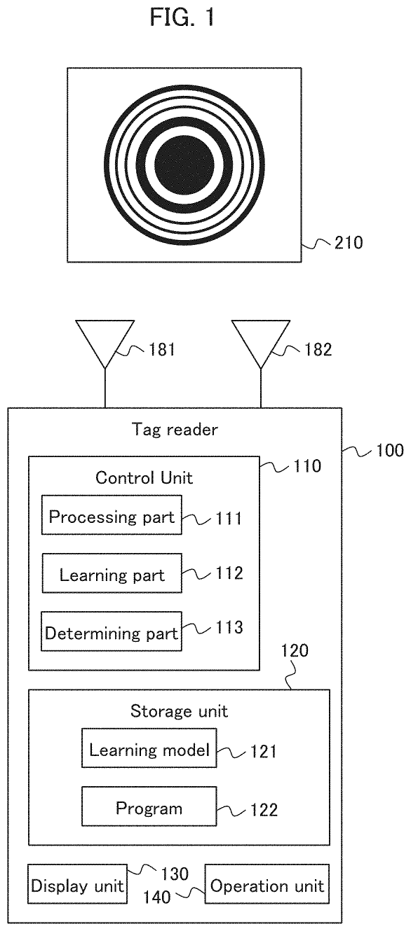

FIG. 1 is a functional block diagram of a tag reader 100 according to the embodiment. The tag reader 100 uses the machine learning technique to scan identification information of the tag from an emergent wave having an incident wave, irradiated to a tag 210 by the tag reader 100, emerged by way of the tag. In particular, the tag reader 100 learns pieces of frequency spectrum information of emergent waves labeled with pieces of identification information of the tag 210 (i.e., ground truth), as teaching data (learning data, training data). After the learning, the tag reader 100 works as a collating device to have information of a frequency spectrum as input data and to output identification information most matching to the input data.

The tag reader 100 includes a control unit 110, a storage unit 120, a display unit 130, an operation unit 140, a transmitting antenna 181, and a receiving antenna 182. The transmitting antenna 181 irradiates the tag 210 with a radio wave in a specific frequency bandwidth. Here, the radio wave is a kind of an electromagnetic wave and has a lower frequency (or longer wavelength) than light. The receiving antenna 182 receives an emergent wave having an incident wave emerged by way of the tag 210. The display unit 130 is a display, for example, to display identification information of the scanned tag 210. The operation unit 140 is a button, for example, and pushing the button causes the tag reader 100 to irradiate the tag 210 with a radio wave (incident wave), obtain identification information of the tag 210 from an emergent wave emerged by way of the tag 210, and display the information on the display unit 130.

The control unit 110 is composed of a CPU (Central Processing Unit) and includes a processing part 111, a learning part 112, and a determining part 113. The processing part 111 irradiates the tag 210 with an incident wave from the transmitting antenna 181, receives by the receiving antenna 182 an emergent wave by way of the tag 210, and produces information of a frequency spectrum as a ratio of intensity of the emergent wave to that of the incident wave. Note that the emergent wave may sometimes be modified due to resonance of the tag 210. Alternatively, the processing part 111 may produce information of a frequency spectrum, using the intensity of the emergent wave instead of the ratio of the intensity of the emergent wave to that of the incident wave.

Note that the information of a frequency spectrum as the ratio of the intensity of the emergent wave to that of the incident wave is also referred to as information of a frequency spectrum of the emergent wave or simply information of a frequency spectrum. In addition, the processing part preferably obtains radio waves in bandwidth of 300 MHz or more and uses two or more analysis points in the radio waves to calculate the information. The radio waves in bandwidth of 500 MHz or more is more preferable, those in bandwidth of 700 MHz or more is particularly preferable, and those in bandwidth of 1000 MHz or more is the most preferable. This is because a wider bandwidth allows for capturing dynamic transition of a wave shape.

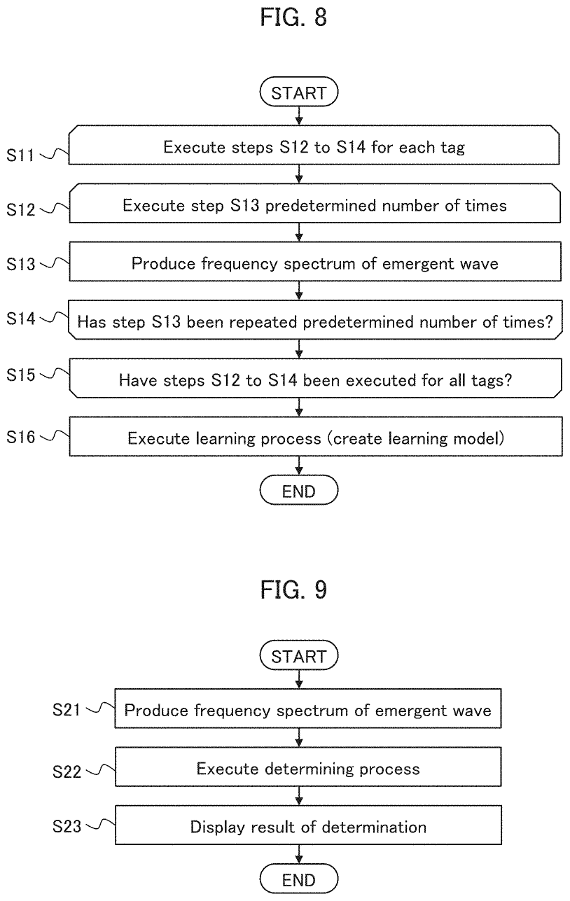

The learning part 112 produces teaching data and learns the data to create a learning model 121 (machine learning model). A procedure of collecting the teaching data and a learning process are described below with reference to FIG. 8. The determining part 113 uses the learning model 121 to scan (obtain) identification information from the information of a frequency spectrum of the emergent wave by way of the tag 210. An obtaining process to scan the identification information of the tag 210 is described below with reference to FIG. 9.

The storage unit 120 is composed of a ROM (Read Only Memory), a RAM (Random Access Memory), a flash memory, or the like to store the learning model 121 and a program 122. The learning model 121 is a model for machine learning. The CPU of the control unit 110 executes the program 122 to serve as the control unit 110.

### <<Configuration of Tag>>

The tag 210 (chipless RFID tag, object to be identified) is not limited to specific objects and includes a cup, a logo, and a mark, and is preferably a radio wave reflector. The radio wave reflector is formed from a base material with low radio wave reflectivity and a metal ink printed on the base material, wherein the metal ink may be replaced with a metal foil transferred to the base material or the like. The tag 210 in FIG. 1 has an independent shape as a tag, but it is not limited thereto and may be a tag using a wrapping package such as paper or plastic as a base material. The tag 210 in FIG. 1 includes areas, printed with a metal ink, in shapes of a circle and four rings with different thicknesses (widths). Note that one or more portions of the tag 210, which is/are printed with a metal ink to reflect radio waves, is/are also referred to as (an) antenna(s) or antenna element(s) of the tag 210.

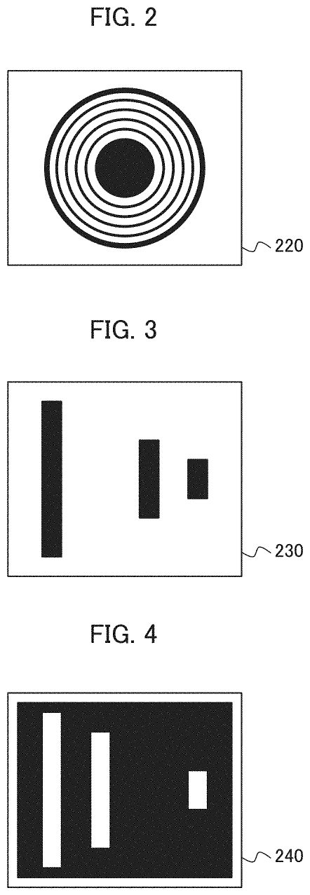

The shape of the antenna (the number and shape of antenna elements) depends on the identification information of the tag. The resonance frequency of the tag varies and the frequency spectrum of the emergent wave varies, according to the shape of the antenna. FIG. 2 shows a tag 220 with identification information different from that of the tag 210 of the embodiment. The tags 210 and 220 both include antennas in a ring shape, but the number and thicknesses of the antennas are different from each other.

FIG. 3 shows a tag 230 in a shape different from that of the tag 210 of the embodiment. The antennas of the tag 230 have rectangular shapes, with different lengths from each other, arranged in parallel to each other. FIG. 4 shows a tag 240 of a transmissive type. The antenna of the tag 240 is in a shape of a metal surface, formed with a metallic ink, partially slit. Note that each of the tags 210 and 220 can also be regarded as a transmissive tag with a circular metal surface annularly and concentrically slit. Other tags with a U-shaped antenna or slit (see Non-Patent Document 1) may also be used. In addition, the shape of the antenna (slit) is not limited to geometric one and may be in a form of a letter or pattern (pattern).

<<Emergent Wave from Tag>>

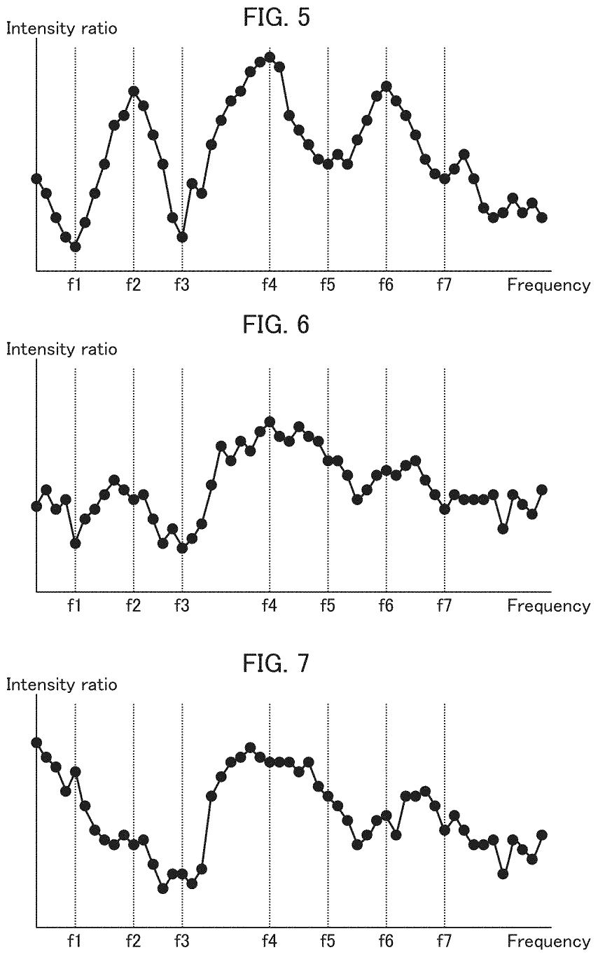

Subsequently, a description is given of a frequency spectrum of an emergent wave by way of the tag 210. FIG. 5 is a first chart to show a frequency spectrum of an emergent wave by way of the tag 210 of the embodiment. The vertical axis indicates the ratio of intensity of the emergent wave (intensity of the radio wave emerged by way of the tag 210) to that of the incident wave. The ratio has troughs at frequencies f1, f3, f5, and f7. In a conventional method, the frequencies having troughs are determined to obtain identification information of the tag 210. In another conventional method, peaks (peak frequencies) at frequencies f2, f4, and f6 are focused to obtain the identification information.

FIG. 6 is a second chart to show a frequency spectrum of an emergent wave by way of the tag 210 of the embodiment. FIG. 6 shows a frequency spectrum in a case where the position and/or orientation of the tag 210 with respect to the transmitting antenna 181 and the receiving antenna 182, and/or objects in vicinity to the tag 210 have been shifted as compared with the case of FIG. 5. Even with the same tag 210, troughs and peaks are difficult to be scanned. For example, the trough at the frequency f5 in FIG. 5 cannot be scanned in FIG. 6. Peaks at the frequencies f2 and f6 in FIG. 5 are also difficult to be scanned.

FIG. 7 is a third chart to show a frequency spectrum of an emergent wave by way of the tag 210 of the embodiment. FIG. 7 shows a frequency spectrum in a case where the position and/or orientation of the tag 210 with respect to the transmitting antenna 181 and the receiving antenna 182, and/or objects in vicinity to the tag 210 have further been shifted as compared with the case of FIG. 6. The troughs and peaks are more difficult to be scanned than those in FIG. 6.

The tag reader 100 creates the learning model 121 by executing machine learning with frequency spectrum information labeled with identification information of the tag as teaching data. Then, the tag reader 100 uses the learning model 121 to obtain the identification information of the tag from the frequency spectrum information. Hereinbelow, the learning process and obtaining process are described.

### <<Learning Process>>

A developer of the tag reader 100 collects teaching data before the learning process is executed. FIG. 8 is a flowchart of a procedure to collect teaching data of the embodiment and execute the learning process. In step S11, the developer executes steps S12 to S14 for each tag. In a case where the identification information of the tag has 8 bits and there are 256 tags, for example, the developer repeats steps S12 to S14 256 times.

In step S12, the developer executes step S13 a predetermined number of times for each tag while shifting the position and/or orientation of the tag with respect to the transmitting antenna 181 and the receiving antenna 182, and objects in vicinity to the tag. In step S13, the developer instructs the tag reader 100 to obtain frequency spectrum of the emergent wave. Upon receiving the instruction, the processing part 111 of the tag reader 100 irradiates the tag with an incident radio wave from the transmitting antenna 181 and obtains the frequency spectrum of the emergent wave received by the receiving antenna 182 by way of the tag. Next, the learning part 112 stores the frequency spectrum information of the emergent wave as teaching data in association with the identification information of the tag inputted by the developer. Note that the information of a frequency spectrum is the ratio of intensity of the emergent wave to that of the incident wave at every predetermined frequency (also referred to as every frequency analysis point).

In step S14, the developer proceeds to step S15 after repeating step S13 a predetermined number of times. If the process has not been repeated a predetermined number of times, the developer shifts the position and/or orientation of the tag, and/or objects in vicinity to the tag, and returns to step S13. In step S15, the developer proceeds to step S16 after executing steps S12 to S14 for all tags. If there is any tag for which teaching data has not been collected, the developer executes steps S12 to S14 for this tag. In step S16, the developer instructs the tag reader 100 to execute the learning process. Upon receiving the instruction, the learning part 112 of the tag reader 100 learns, using the teaching data stored and collected in step S13, to create the learning model 121 (to train the learning model 121 with the teaching data).

### <<Obtaining Process>>

FIG. 9 is a flowchart of the obtaining process of the embodiment. A description is given of the obtaining process (determining process, collating process) of the identification information using the machine learning technique executed by the determining part 113, with reference to FIG. 9. In step S21, the determining part 113 instructs the processing part 111 to irradiate the tag with an incident radio wave from the transmitting antenna 181 and obtains information of a frequency spectrum of an emergent wave received by the receiving antenna 182 by way of the tag.

In step S22, the determining part 113 executes the determining process. In particular, the determining part 113 inputs the information of a frequency spectrum to the learning model 121 and obtains the identification information of the tag as an output. Note that when the learning model 121 outputs two or more pieces of identification information, the determining part 113 obtains identification information having the highest probability. In step S23, the determining part 113 displays the identification information, as a result of determination, on the display unit 130.

### <<Advantageous Effects of Leaning Process and Obtaining Process>>

As shown in FIGS. 5 to 7, even with the same tag, the frequency spectrum varies depending on the position and orientation of the tag and objects in vicinity to the tag, and thus it is difficult to determine the resonance frequency. The tag reader 100 uses the learning model 121, which has learned the frequency spectrum information labeled with the identification information as the teaching data, to obtain the identification information of the tag from the information of a frequency spectrum. In particular, the tag reader 100 uses the frequency spectrum information for every identification information, included in the teaching data, as registration information, to determine identification information of the frequency spectrum information, whose frequency spectrum is the most analogous to the information of a frequency spectrum, among the registration information, and output the identification information as a result of the obtaining process (determining process, collating process). The teaching data includes frequency spectrum information having no troughs and/or peaks that should supposedly be present in the frequency spectrum, for example. This allows the tag reader 100 to output the identification information even for the information of a frequency spectrum having no troughs and/or peaks (at the resonance frequencies of the antennas) which should supposedly be present.

Using the machine learning technique allows the tag reader 100 to obtain the identification information with high accuracy, as compared with a conventional method. In addition, the identification information can be obtained even in a case where the position and/or orientation of the tag is/are not constant and/or there is/are (an) object(s) in vicinity to the tag (high robustness). For example, the identification information can be obtained even in a case where there are no troughs and peaks that should supposedly present in a frequency spectrum (see FIG. 7). As a result, restrictions on the shape of the tag 210 are relaxed, and the scanning accuracy of the tag 210 is improved.

SVM (Support Vector Machine), k-nearest neighbor algorithm, random forest, or the like may be used, or ensemble learning using these machine learning techniques may be used, as the machine learning technology (machine learning model). In addition, hyperparameters of the learning model 121 as a result of the learning may be optimized with a grid search.

### <<Modification: Resonance Frequency and Frequency Analysis Point>>

The frequency analysis point, which is a frequency for calculating the intensity ratio to be included in the information of a frequency spectrum, may be a resonance frequency of the antenna (antenna element) of the tag, or may include a frequency different from the resonance frequency. The processing part 111 generates information of a frequency spectrum so that the number of frequency analysis points is larger than the number of attributes of the identification information. Regarding the attributes of the identification information, the identification information is assumed to be bit information, with each bit representing an attribute, and the number of frequency analysis points is set larger than the bit length. For example, when the identification information has 8 bits, the number of frequency analysis points is set larger than 8. Note that the identification information is one of the attributes of the tag, and each bit of the identification information can be regarded as the attribute of the tag, as will be described below.

### <<Modification: Learning Device and Collating Device>>

In the embodiment as described above, the tag reader 100 executes both the learning process and the obtaining process (determining process, collating process). In contrast, the learning process may be executed by a device different from the device to execute the obtaining process. A learning device, including the processing part 111 and the learning part 112 but not including the determining part 113, may execute the learning process to create the learning model 121. In addition, a collating device, including the processing part 111 and the determining part 113 and storing the learning model 121 created by the learning device, may execute the obtaining process.

Separating the learning device from the collating device, as described above, allows for reducing time and effort required for learning with each collating device. In addition, the machine learning process generally requires higher processing costs for the learning process than those for the collating process. Having the collating device not executing the learning process allows for lowering the hardware specifications required for the collating device, to reduce costs.

### <<Modification: Tag Reader>>

In the embodiment as described above, the tag reader 100 includes the transmitting antenna 181 and receiving antenna 182, irradiates the tag 210 with an incident radio wave in a specific frequency band, and receives an emergent wave by way of the tag 210. In contrast, a transmitting antenna and a receiving antenna may respectively be provided in devices different from each other, to radiate a radio wave from one device and receive a radio wave by the other device. For example, a device including a transmitting antenna and a device including a receiving antenna may be placed on opposite sides of the tag, and the device including the transmitting antenna irradiates the tag with an incident radio wave while the device including the receiving antenna scans an emergent wave emerged by way of the tag to obtain the identification information.

<<Modification: Data obtained from Emergent Wave>>

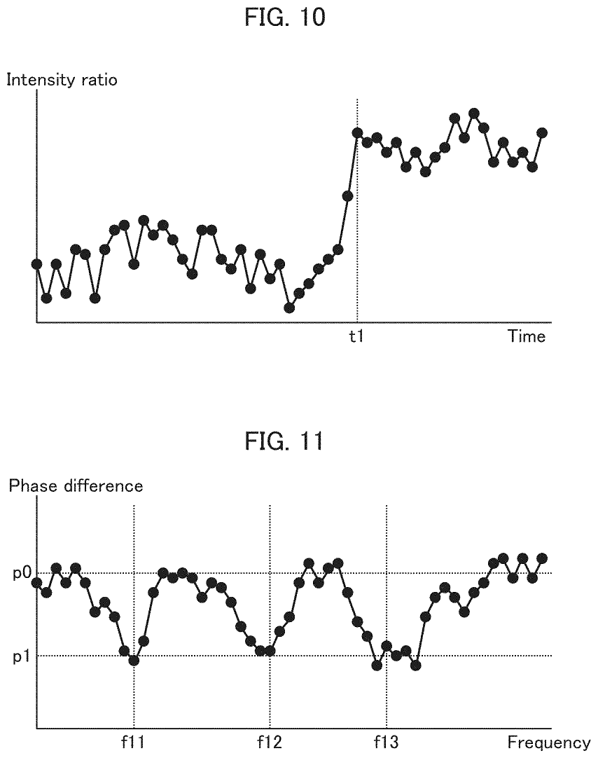

In the embodiment as described above, the tag reader 100 uses the information of a frequency spectrum of the emergent wave by way of the tag. Other information of the emergent wave may be used instead. FIG. 10 is a chart to show an intensity ratio in the time domain, according to a modification of the embodiment. FIG. 10 shows the ratio of intensity of the emergent wave to that of the incident wave after the tag has been irradiated with the incident wave, and the emergent wave is received after time t1. Executing spectral analysis (Fourier transform) on the intensity ratio after time t1 gives the frequency spectra shown in FIGS. 5 to 7. Instead of the frequency spectrum, a learning model may be used that has learned chronological data on the intensity ratio of the emergent wave, shown in FIG. 10, to execute the obtaining process for the identification information.

FIG. 11 is a chart to show a phase difference in the frequency domain, according to a modification of the embodiment. A phase shift from p0 (0 degrees) to p1 (180 degrees) occurs at around the resonance frequencies f11, f12, and f13 of the tag. Instead of the frequency spectrum, a learning model may be used that has learned phase differences (phase characteristics) in the frequency domain of the emergent wave, shown in FIG. 12, to execute the obtaining process for the identification information. The frequency analysis points, where the phase differences are obtained, may be the resonance frequencies of the antennas (antenna elements) of the tag, or may include frequencies different from the resonance frequencies. The phase characteristic in the time domain may be used instead of the frequency domain. Alternatively, a learning model may be used that has learned both the frequency spectrum information and the phase characteristics, to execute the obtaining process for the identification information.

<<Modification: Item to be identified>>

In the embodiment as described above, the tag reader 100 learns the teaching data labeled with identification information of tags, to obtain identification information of the tag. The tag reader 100 may obtain orientation of the tag with respect to the transmitting antenna 181 and the receiving antenna 182, in addition to the identification information. In particular, the tag reader 100 learns the frequency spectrum information labeled with the identification information and orientation of tags, as teaching data. Then, the tag reader 100 can obtain the orientation in addition to the identification information from the information of a frequency spectrum. Note that other information for determination, such as being a dielectric substance, can thus be added to the identification information, in addition to the orientation, depending on application, and such pieces of information affecting the identification information are referred to as attributes of the tag. An example of producing teaching data is described below in a case where attributes of the tag are provided.

Antennas (slits) of a tag in terms of a shape, whose orientation can be obtained, include antennas having vertically long rectangles and horizontally long rectangles aligned, and a U-shaped antenna, in addition to rectangular antennas (see FIG. 3). Alternatively, two transmitting antennas 181 and two receiving antennas 182 may be provided to use two pieces of information of frequency spectra of a horizontally polarized wave and a vertically polarized wave for obtaining the identification information and orientation of the tag. In order to indicate whether the orientation is vertical or horizontal, attributes of the orientation involve one or more frequency analysis points of horizontally polarized wave and one or more frequency analysis points of a vertically polarized wave, and the number of frequency analysis points is greater than 1.

The orientation being an attribute or not can be changed depending on application. When the orientation is not desired to be an attribute, a learning model is built using pieces of information obtained by rotating the tag in all directions, as teaching data having the same identification information (ground truth label). In contrast, when the orientation is desired to be an attribute, a learning model is built using vertical and horizontal orientations, as teaching data having separate attributes. Variation in dielectric constant and variation in dielectric dissipation factor, in vicinity to the tag, can also be attributes, depending on application. When these are desired to be attributes, a learning model is built using presence of a dielectric substance behind the tag and absence of the same, as teaching data having separate attributes (ground truth labels), for example. An example of the dielectric substance include moisture.

Likewise, presence of a conducting substance in vicinity to the tag can be an attribute. When this is desired to be an attribute, a learning model is built using presence of metal behind the tag and absence of the same, as teaching data having separate attributes (ground truth labels), for example. Deterioration of the tag can also be an attribute. When this is desired to be an attribute, a learning model can be built using information before and after deterioration of the tag, as teaching data having separate attributes (ground truth labels). Deterioration of the tag includes sulfurization of silver used for the antenna of the tag.

### <<Modification: Collecting Teaching Data>>

In steps S12 to S14 (see FIG. 8), the developer collects teaching data while shifting objects in vicinity (within a predetermined distance) to the tag. The object is not limited to a conductive substance such as a metal foil, and include a dielectric substance such as paper, a PET circuit board (flexible printed circuit), and water, which has any of the dielectric constant, dielectric dissipation factor, and electric conductivity different from that of the tag antenna. The collected data (the intensity of the emergent wave, the ratio of intensity of the emergent wave to that of the incident wave, the phase difference between the incident wave and the emergent wave) includes one or more pieces of data having no peaks and no troughs at the one or more resonance frequencies of the antennas.

Hereinabove, embodiments of the present invention have been described, but these embodiments are merely examples and are not intended to limit the technical scope of the present invention. The present invention can take various other forms of embodiments, and further, various modifications such as deletion and replacement can be made within the scope of the present invention. These embodiments and modifications thereof are included in the scope and summary of the invention as described above and are also included in the scope of the invention claimed in appended claims and the equivalents thereto.

### LEGEND FOR REFERNCE NUMERALS

100: tag reader (learning device, collating device), 111: processing part, 112: learning part, 113: determining part, 121: leaning model (machine learning model), 122: program, and 210; 220; 230; 240: tag (RFID tag, radio wave reflector, object to be identified).

What is claimed is:

1. A collating device comprising:
a processing part configured to output information calculated from an emergent wave having an incident wave, as a radio wave irradiated to an object to be identified, emerged by way of the object; and
a determining part configured to identify one or more attributes of the object, using the information.

2. The collating device according to claim 1, wherein
the information includes at least intensity of the emergent wave.

3. The collating device according to claim 2, wherein
the information includes the at least intensity of the emergent wave at every frequency analysis point.

4. The collating device according to claim 1, wherein
information is a ratio of intensity of the emergent wave to that of the incident wave and/or a phase difference between the incident wave and the emergent wave, at every frequency analysis point.

5. The collating device according to claim 1, wherein
the processing part collects waves having a bandwidth of 300 MHz or more and uses two or more frequency analysis points within the bandwidth to calculate the information.

6. The collating device according to claim 1, wherein
the information is at least one of intensity of the emergent wave, a ratio of the intensity of the emergent wave to that of the incident wave, and a phase difference between the incident wave and the emergent wave, at every frequency analysis point in time domain.

7. The collating device according to claim 1, wherein
the one or more attributes are given by one or more antenna elements of the object.

8. The collating device according to claim 7, wherein
the determining part uses, as the information, at least one of intensity of the emergent wave, a ratio of the intensity of the emergent wave to that of the incident wave, and a phase difference between the incident wave and the emergent wave, at every frequency analysis point other than resonance frequencies of the one or more antenna elements.

9. The collating device according to claim 7: wherein
the attributes of the object are identified by the determining part, even in a case where there are no peaks in at least one of intensity of the emergent wave, a ratio of the intensity of the emergent wave to that of the incident wave, and a phase difference between the incident wave and the emergent wave, at resonance frequencies of the one or more antenna elements of the object.

10. The collating device according to claim 7, wherein
the determining part uses, as the information, at least one of intensity of the emergent wave, a ratio of the intensity of the emergent wave to that of the incident wave, and a phase difference between the incident wave and the emergent wave, at each of frequency analysis points the number of which is greater than that of the identified one or more attributes of the object.

11. The collating device according to claim 1, wherein
the one or more attributes include an orientation of the object.

12. The collating device according to claim 1, wherein
the determining part identifies the one or more attributes of the object, based on a degree of similarity of the information to registered information on the one or more attributes of the object.

13. The collating device according to claim 1, wherein
the determining part identifies the one or more attributes of the object, using a machine learning model.

14. The collating device according to claim 13, wherein
the machine learning model results from learning teaching data having pieces of information on the one or more attributes obtained from the object associated with labels of the one or more attributes.

15. The collating device according to claim 14, wherein
the teaching data includes data in a case where there are no peaks in at least one of intensity of the emergent wave, a ratio of the intensity of the emergent wave to that of the incident wave, and a phase difference between the incident wave and the emergent wave, at resonance frequencies of the one or more antenna elements of the object.

16. The collating device according to claim 13, wherein
the machine learning model uses one of the SVM (Support Vector Machine), k-nearest neighbor algorithm, and random forests.

17. The collating device according to claim 13, wherein
the machine learning model uses ensemble leaning including at least one of the SVM, k-nearest neighbor algorithm, and random forests.

18. The collating device according to claim 13, wherein
hyperparameters of the machine learning model are optimized with a grid search.

19. A learning device comprising:
a processing part configured to output information calculated from an emergent wave having an incident wave, as a radio wave irradiated to an object to be identified, emerged by way of the object; and
a learning part configured to create a machine learning model by learning teaching data having the information associated with labels of one or more attributes of the object.

20. The learning device according to claim 19, wherein
the teaching data includes pieces of information calculated from emergent waves measured with positions or orientations of the object being respectively different from one another with respect to an antenna radiating the incident wave and an antenna receiving the emergent wave.

21. The learning device according to claim 19, wherein
of the teaching data is information calculated from the emergent wave measured with a conducting or dielectric substance arranged within a predetermined distance from the object.

22. A non-transitory computer-readable medium storing a computer-executable program which, when executed by a computer with an antenna, causes the computer to execute:
a step of outputting information calculated from an emergent wave having an incident wave, as a radio wave irradiated to an object to be identified, emerged by way of the object; and
a step of identifying one or more attributes of the object, using the information.

23. A non-transitory computer-readable medium storing a computer-executable program which, when executed by a computer with an antenna, causes the computer to execute:
a step of outputting information calculated from an emergent wave having an incident wave, as a radio wave irradiated to an object to be identified, emerged by way of the object; and
a step of creating a machine learning model by learning teaching data having the information associated with labels of one or more attributes of the object.
